(19) United States
(12) Patent Application Publication
(10) Pub. No.: US 2025/0098471 A1
(43) Pub. Date: Mar. 20, 2025

(54) DISPLAY PANEL, DISPLAY APPARATUS, AND LIGHT EMITTING SUBSTRATE

(71) Applicant: BOE Technology Group Co., Ltd., Beijing (CN)

(72) Inventors: Guang Yan, Beijing (CN); Linlin Wang, Beijing (CN); Jinglu Bai, Beijing (CN)

(73) Assignee: BOE Technology Group Co., Ltd., Beijing (CN)

(21) Appl. No.: 18/572,526

(22) PCT Filed: Dec. 20, 2022
(86) PCT No.: PCT/CN2022/140180

§ 371 Date: Dec. 20, 2023

(51) Int. Cl. H10K 59/38; H10K 59/00; H10K 59/122; H10K 59/35

(52) U.S. Cl. CPC H10K 59/38; H10K 59/122; H10K 59/352; H10K 59/771

(57) ABSTRACT

A display panel includes a first subpixel region configured to emit light of a first color, a second subpixel region configured to emit light of a second color, and a third subpixel region configured to emit light of a third color. The display panel includes a first light-emitting diode including a first light emitting layer, a second light emitting diode including a second light emitting layer, and a third light-emitting diode including a third light emitting layer. The second light emitting layer and the third light emitting layer are spaced apart from each other. At least a first portion of the first light emitting layer and the third light emitting layer are parts of a unitary layer continuously extending from the third subpixel region to at least a first portion of the first subpixel region. The third subpixel region is smaller than the second subpixel region.

### TECHNICAL FIELD

The present invention relates to display technology, more particularly, to a display panel, a display apparatus, and a light emitting substrate.

### BACKGROUND

Quantum dots material has excellent optical and electrical properties, including a narrow emission peak (with a half-peak width of approximately 30 nm), a tunable spectrum (ranging from visible light to infrared light), high photochemical stability, and a low starting voltage. Wavelengths of light emitted from quantum dots materials are tunable at least in part based on the particle sizes of the quantum dots. Due to these excellent properties, quantum dots have become a focus of research and development in the fields of display technology.

### SUMMARY

In one aspect, the present disclosure provides a display panel, comprising a first subpixel region configured to emit light of a first color, a second subpixel region configured to emit light of a second color, and a third subpixel region configured to emit light of a third color; wherein the display panel comprises a base substrate; and a first light-emitting diode, a second light emitting diode, and a third light-emitting diode on the base substrate; wherein the first light-emitting diode comprises a first light emitting layer; the second light emitting diode comprises a second light emitting layer; the third light-emitting diode comprises a third light emitting layer; the second light emitting layer and the third light emitting layer are spaced apart from each other; at least a first portion of the first light emitting layer and the third light emitting layer are parts of a unitary layer continuously extending from the third subpixel region to at least a first portion of the first subpixel region; an area of the third subpixel region is smaller than an area of the second subpixel region, and is smaller than an area of the first subpixel region; and the first color, the second color, and the third color are three different colors.

Optionally, at least a second portion of the first light emitting layer and the second light emitting layer are parts of a unitary layer continuously extending from the second subpixel region to at least a second portion of the first subpixel region.

Optionally, the light of the third color has a wavelength range smaller than a wavelength range of the light of the first color, and smaller than a wavelength range of the light of the second color.

Optionally, the display panel further comprises a first emissive material layer; wherein the first emissive material layer comprises the third light emitting layer and the first portion of the first light emitting layer; and the third light emitting layer and the first portion of the first light emitting layer have a same composition.

Optionally, the first emissive material layer comprises a stacked structure comprising multiple first emissive material sub-layers.

Optionally, at least two of the multiple first emissive material sub-layers are emissive material sub-layers of a same color.

Optionally, all of the multiple first emissive material sub-layers are emissive material sub-layers of a same color.

Optionally, at least two of the multiple first emissive material sub-layers are emissive material sub-layers of different colors.

Optionally, the multiple first emissive material sub-layers comprise an emissive material sub-layer of the first color and an emissive material sub-layer of the third color.

Optionally, the display panel comprises a second emissive material layer; wherein the second emissive material layer comprises the second light emitting layer and the second portion of the first light emitting layer; and the second light emitting layer and the second portion of the first light emitting layer have a same composition.

Optionally, the second emissive material layer comprising a stacked structure comprising multiple second emissive material sub-layers.

Optionally, at least two of the multiple second emissive material sub-layers are emissive material sub-layers of different colors.

Optionally, the display panel further comprises a second emissive material layer; wherein the first emissive material layer comprises a stacked structure comprising one or more first emissive material sub-layers of a third color, the one or more first emissive material sub-layers being configured to emit light of the third color with a first peak wavelength; the second emissive material layer comprises a stacked structure comprising one or more second emissive material sub-layers of the third color, the one or more second emissive material sub-layers being configured to emit light of the third color with a second peak wavelength; the first peak wavelength and the second peak wavelength are in a wavelength range of blue light; and the first peak wavelength is different from the second peak wavelength.

Optionally, the first peak wavelength is in a range of 460 nm to 463 nm, and the second peak wavelength is in a range of 450 nm to 454 nm.

Optionally, the first emissive material layer comprises a stacked structure comprising one or more first emissive material sub-layers configured to emit light of the third color, and at least one emissive material sub-layer configured to emit light of the first color, the at least one emissive material sub-layer being on a side of the one or more first emissive material sub-layers away from the base substrate.

Optionally, the second emissive material layer comprises a stacked structure comprising one or more second emissive material sub-layers configured to emit light of the third color, and at least one emissive material sub-layer configured to emit light of the second color, the at least one emissive material sub-layer being on a side of the one or more second emissive material sub-layers away from the base substrate.

Optionally, the display panel further comprises a color conversion layer and a light transmissive layer; wherein the color conversion layer comprises a plurality of first color conversion blocks of a first color; the light transmissive layer comprises a plurality of light transmissive blocks configured to allow light to transmit through; an individual light transmissive block of the plurality of light transmissive blocks is at least partially in the third subpixel region; a first individual first color conversion block of the plurality of first color conversion blocks of the first color is at least partially in the first subpixel region; and light provided to at least a portion of the first subpixel region and to the third subpixel region are of a same color.

Optionally, the display panel comprises a first emissive material layer; wherein the first emissive material layer comprises the third light emitting layer and the first portion of the first light emitting layer; and the third light emitting layer and the first portion of the first light emitting layer have a same composition; wherein an orthographic projection of the first emissive material layer on the base substrate at least partially overlaps with an orthographic projection of the individual light transmissive block in the third subpixel region on the base substrate, and at least partially overlaps with an orthographic projection of the first individual first color conversion block in at least the portion of the first subpixel region on the base substrate.

Optionally, the display panel further comprises a bank layer defining a plurality of apertures for receiving a plurality of color conversion blocks and the plurality of light transmissive blocks; wherein the orthographic projection of the first emissive material layer on the base substrate at least partially overlaps with an orthographic projection of a portion of the bank layer spacing apart the individual light transmissive block and the first individual first color conversion block on the base substrate.

Optionally, the first subpixel region comprises a first subpixel second region; wherein the color conversion layer further comprises a plurality of second color conversion blocks of a second color; an individual second color conversion block of the plurality of second color conversion blocks of the second color is at least partially in the second subpixel region; a second individual first color conversion block of the plurality of first color conversion blocks of a first color is at least partially in the first subpixel second region; and light provided to the second subpixel region and the first subpixel second region are of a same color.

Optionally, the display panel comprises a second emissive material layer; wherein the second emissive material layer comprises the second light emitting layer and a second portion of the first light emitting layer; and the second light emitting layer and the second portion of the first light emitting layer have a same composition; wherein an orthographic projection of the second emissive material layer on the base substrate at least partially overlaps with an orthographic projection of the individual second color conversion block in the second subpixel region on the base substrate, and at least partially overlaps with an orthographic projection of the second individual first color conversion block in the first subpixel second region on the base substrate.

Optionally, the display panel further comprises a bank layer defining a plurality of apertures for receiving a plurality of color conversion blocks and the plurality of light transmissive blocks; wherein the orthographic projection of the second emissive material layer on the base substrate at least partially overlaps with an orthographic projection of a portion of the bank layer spacing apart the individual second color conversion block and the second individual first color conversion block on the base substrate.

In another aspect, the present disclosure provides a display apparatus, comprising the display panel described herein, and one or more integrated circuits connected to the display panel.

In another aspect, the present disclosure provides a light emitting substrate, comprising a first subpixel region configured to emit light of a first color, a second subpixel region configured to emit light of a second color, and a third subpixel region configured to emit light of a third color; wherein the light emitting substrate comprises a base substrate; and a first light-emitting diode, a second light emitting diode, and a third light-emitting diode on the base substrate; wherein the first light-emitting diode comprises a first light emitting layer; the second light emitting diode comprises a second light emitting layer; the third light-emitting diode comprises a third light emitting layer; the second light emitting layer and the third light emitting layer are spaced apart from each other; at least a first portion of the first light emitting layer and the third light emitting layer are parts of a unitary layer continuously extending from the third subpixel region to at least a first portion of the first subpixel region; an area of the third subpixel region is smaller than an area of the second subpixel region, and is smaller than an area of the first subpixel region; and the first color, the second color, and the third color are three different colors.

Optionally, at least a second portion of the first light emitting layer and the second light emitting layer are parts of a unitary layer continuously extending from the second subpixel region to at least a second portion of the first subpixel region.

Optionally, the light of the third color has a wavelength range smaller than a wavelength range of the light of the first color, and smaller than a wavelength range of the light of the second color.

Optionally, the light emitting substrate comprises a first emissive material layer; wherein the first emissive material layer comprises the third light emitting layer and the first portion of the first light emitting layer; and the third light emitting layer and the first portion of the first light emitting layer have a same composition.

Optionally, the first emissive material layer comprises a stacked structure comprising multiple first emissive material sub-layers.

Optionally, at least two of the multiple first emissive material sub-layers are emissive material sub-layers of a same color.

Optionally, all of the multiple first emissive material sub-layers are emissive material sub-layers of a same color.

Optionally, at least two of the multiple first emissive material sub-layers are emissive material sub-layers of different colors.

Optionally, the light emitting substrate comprises a second emissive material layer; wherein the second emissive material layer comprises the second light emitting layer and the second portion of the first light emitting layer; and the second light emitting layer and the second portion of the first light emitting layer have a same composition.

Optionally, the second emissive material layer comprising a stacked structure comprising multiple second emissive material sub-layers.

Optionally, at least two of the multiple second emissive material sub-layers are emissive material sub-layers of different colors.

Optionally, the light emitting substrate further comprises a second emissive material layer; wherein the first emissive material layer comprises a stacked structure comprising one or more first emissive material sub-layers of a third color, the one or more first emissive material sub-layers being configured to emit light of the third color with a first peak wavelength; the second emissive material layer comprises a stacked structure comprising one or more second emissive material sub-layers of the third color, the one or more second emissive material sub-layers being configured to emit light of the third color with a second peak wavelength; the first peak wavelength and the second peak wavelength are in a wavelength range of blue light; and the first peak wavelength is different from the second peak wavelength.

Optionally, the first peak wavelength is in a range of 460 nm to 463 nm, and the second peak wavelength is in a range of 450 nm to 454 nm.

Optionally, the first emissive material layer comprises a stacked structure comprising one or more first emissive material sub-layers configured to emit light of the third color, and at least one emissive material sub-layer configured to emit light of the first color, the at least one emissive material sub-layers being on a side of the one or more first emissive material sub-layer away from the base substrate.

Optionally, the second emissive material layer comprises a stacked structure comprising one or more second emissive material sub-layers configured to emit light of the third color, and at least one emissive material sub-layer configured to emit light of the second color, the at least one emissive material sub-layer being on a side of the one or more second emissive material sub-layers away from the base substrate.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a display panel in some embodiments according to the present disclosure.

FIG. 2 is a cross-sectional view along an A-A′ line in FIG. 1.

FIG. 3 is a plan view of a display panel in some embodiments according to the present disclosure.

FIG. 4 is a cross-sectional view of a display panel in some embodiments according to the present disclosure.

FIG. 5 is a cross-sectional view of a display panel in some embodiments according to the present disclosure.

FIG. 6A is a schematic diagram illustrating the structure of a first color conversion block in some embodiments according to the present disclosure.

FIG. 6B is a schematic diagram illustrating the structure of a second color conversion block in some embodiments according to the present disclosure.

FIG. 6C is a schematic diagram illustrating the structure of a light scattering block in some embodiments according to the present disclosure.

FIG. 7 is a cross-sectional view of a display panel in some embodiments according to the present disclosure.

FIG. 8A is a schematic diagram illustrating a first emissive material layer and a second emissive material layer in a display panel in some embodiments according to the present disclosure.

FIG. 8B is a schematic diagram illustrating a first emissive material layer and a second emissive material layer in a display panel in some embodiments according to the present disclosure.

FIG. 8C is a schematic diagram illustrating a first emissive material layer and a second emissive material layer in a display panel in some embodiments according to the present disclosure.

FIG. 8D is a schematic diagram illustrating a first emissive material layer and a second emissive material layer in a display panel in some embodiments according to the present disclosure.

FIG. 9 is a cross-sectional view of a display panel in some embodiments according to the present disclosure.

FIG. 10 is a cross-sectional view of a display panel in some embodiments according to the present disclosure.

FIG. 11 is a cross-sectional view of a display panel in some embodiments according to the present disclosure.

FIG. 12 is a cross-sectional view of a display panel in some embodiments according to the present disclosure.

FIG. 13A is a schematic diagram illustrating a first emissive material layer and a second emissive material layer in a display panel in some embodiments according to the present disclosure.

FIG. 13B is a schematic diagram illustrating a first emissive material layer and a second emissive material layer in a display panel in some embodiments according to the present disclosure.

FIG. 14A is a schematic diagram illustrating a first emissive material layer and a second emissive material layer in a display panel in some embodiments according to the present disclosure.

FIG. 14B is a schematic diagram illustrating a first emissive material layer and a second emissive material layer in a display panel in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a display panel, a display apparatus, and a light emitting substrate that substantially obviate one or more of the problems due to limitations and disadvantages of the related art. In one aspect, the present disclosure provides a display panel. In some embodiments, the display panel includes a first subpixel region configured to emit light of a first color, a second subpixel region configured to emit light of a second color, and a third subpixel region configured to emit light of a third color. In some embodiments, the display panel includes a base substrate; and a first light-emitting diode, a second light emitting diode, and a third light-emitting diode on the base substrate. Optionally, the first light-emitting diode includes a first light emitting layer; the second light emitting diode includes a second light emitting layer; and the third light-emitting diode includes a third light emitting layer. Optionally, the second light emitting layer and the third light emitting layer are spaced apart from each other. Optionally, at least a first portion of the first light emitting layer and the third light emitting layer are parts of a unitary layer continuously extending from the third subpixel region to at least a first portion of the first subpixel region. Optionally, an area of the third subpixel region is smaller than an area of the second subpixel region, and is smaller than an area of the first subpixel region. Optionally, the first color, the second color, and the third color are three different colors.

The inventors of the present disclosure discover that the display panel according to the present disclosure achieves an improved light emission efficiency in subpixels of a first color (e.g., red subpixels), reduces the color shift issue in subpixels of a second color (e.g., correcting the issue of color shift towards yellow in green subpixels), and achieves a higher brightness in subpixels of a third color (e.g., blue subpixels). The display panel is more conducive to eyesight.

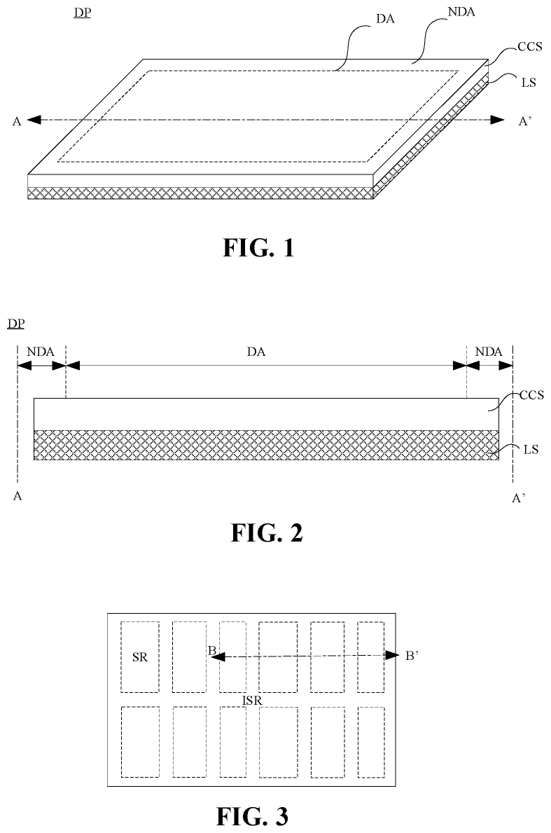

FIG. 1 is a schematic diagram illustrating the structure of a display panel in some embodiments according to the present disclosure. FIG. 2 is a cross-sectional view along an A-A′ line in FIG. 1. Referring to FIG. 1 and FIG. 2, the display panel DP in some embodiments includes a light emitting substrate LS and a color conversion substrate CCS. The display panel DP includes a display area DA and a non-display area NDA.

FIG. 3 is a plan view of a display panel in some embodiments according to the present disclosure. Referring to FIG. 3, the display panel in some embodiments includes a plurality of subpixel region SR and an inter-subpixel region ISR. As used herein, a subpixel region refers to a light emission region of a subpixel, such as a region corresponding to a pixel electrode in a liquid crystal display, or a region corresponding to a light emissive layer in a light-emitting diode display panel, or a region corresponding to a color conversion block in a display panel according to the present disclosure. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel. As used herein, an inter-subpixel region refers to a region between adjacent subpixel regions, such as a region corresponding to a black matrix in a liquid crystal display, or a region corresponding a pixel definition layer in a light-emitting diode display panel, or a region corresponding to a bank layer in a display panel according to the present disclosure. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

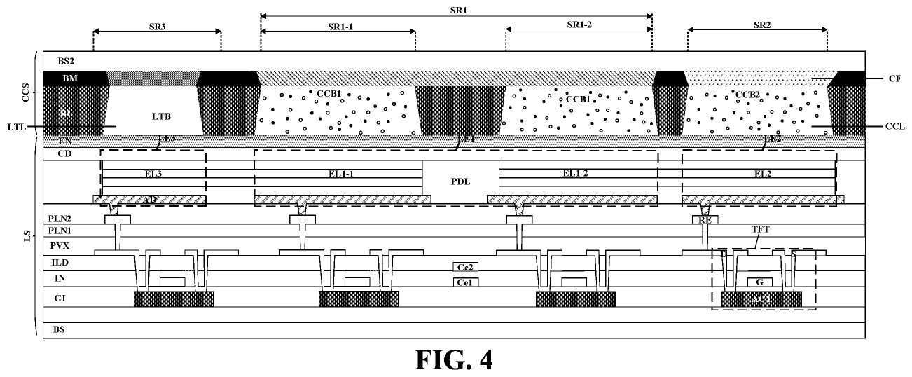

FIG. 4 is a cross-sectional view of a display panel in some embodiments according to the present disclosure. FIG. 4 may be a cross-sectional, for example, along a B-B′ line in FIG. 3. Referring to FIG. 4, the display panel in some embodiments includes a light emitting substrate LS and a color conversion substrate CCS on the light emitting substrate LS. In some embodiments, the light emitting substrate includes a base substrate BS; an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first gate metal layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second gate metal layer) on a side of the insulating layer IN away from the gate insulating layer GI; an inter-layer dielectric layer ILD on a side of the second capacitor electrode Ce2 away from the gate insulating layer GI; a source electrode S and a drain electrode D (parts of a first SD metal layer) on a side of the inter-layer dielectric layer ILD away from the gate insulating layer GI; a passivation layer PVX on a side of the source electrode S and the drain electrode D away from the inter-layer dielectric layer ILD; a first planarization layer PLN1 on a side of the passivation layer PVX away from the inter-layer dielectric layer ILD; a relay electrode RE (part of a second SD metal layer) on side of the first planarization layer PLN1 away from the passivation layer PVX; a second planarization layer PLN2 on a side of the relay electrode RE (part of a second SD metal layer) away from the first planarization layer PLN1; a pixel definition layer PDL defining a subpixel aperture and on a side of the second planarization layer PLN2 away from the base substrate BS; a light-emitting diode (e.g., a first light-emitting diode LE1, a second light-emitting diode LE2, and a third light-emitting diode LE3 denoted in FIG. 4) in the subpixel aperture; and an encapsulating layer EN on a side of the light-emitting diode away from the base substrate BS. The encapsulating layer EN encapsulates the light-emitting diode.

In some embodiments, a respective light-emitting diode includes an anode AD on the base substrate BS, a light emitting layer (e.g., a first light emitting layer EL1, a second light emitting layer EL2, and a third light emitting layer EL3) on a side of the anode AD away from the base substrate BS, and a cathode CD on a side of the light emitting layer away from the base substrate BS.

In some embodiments, the color conversion substrate CCS includes a second base substrate BS2, a black matrix BM and a color filter CF on the second base substrate BS2, a bank layer BL defining a plurality of apertures on a side of the black matrix BM away from the second base substrate BS2, a color conversion layer CCL and a light transmissive layer LTL at least partially in the plurality of apertures defined by the bank layer BL. In some embodiments, the color conversion layer CCL includes a plurality of color conversion blocks, e.g., a plurality of first color conversion blocks of a first color CCB1 and a plurality of second color conversion blocks of a second color CCB2. The light transmissive layer LTL includes a plurality of light transmissive blocks LTB.

In some embodiments, the light transmissive layer LTL is absent of color conversion materials such as quantum dots materials. The plurality of light transmissive blocks LTB are absent of color conversion materials such as quantum dots materials. As shown in FIG. 4, the light transmissive layer LTL (including the plurality of light transmissive blocks LTB) includes a substantially transparent insulating material.

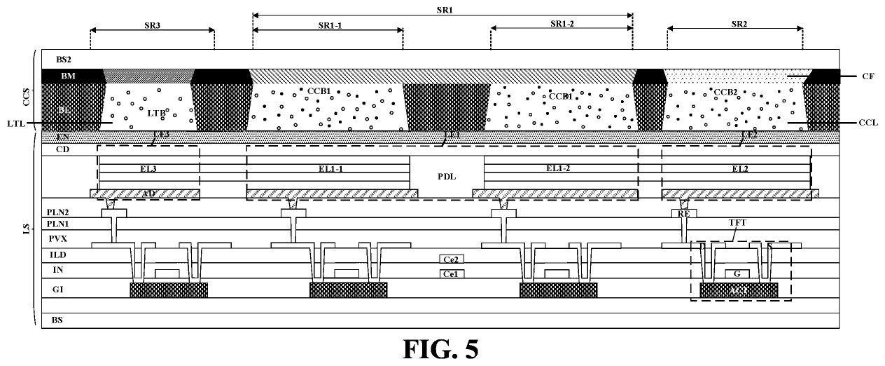

FIG. 5 is a cross-sectional view of a display panel in some embodiments according to the present disclosure. Referring to FIG. 5, in some embodiments, the light transmissive layer LTL is a light scattering layer, and the plurality of light transmissive blocks LTB are a plurality of light scattering blocks.

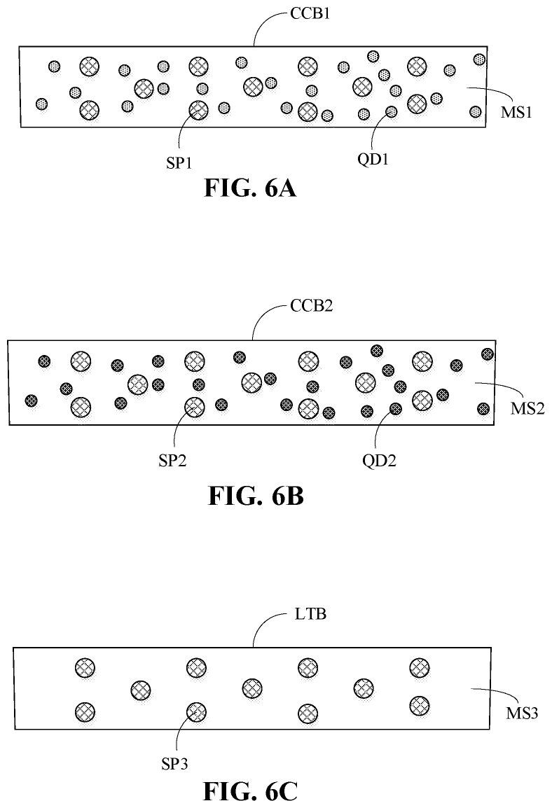

FIG. 6A is a schematic diagram illustrating the structure of a first color conversion block in some embodiments according to the present disclosure. Referring to FIG. 6A, the plurality of first color conversion blocks of a first color CCB1 are color conversion blocks configured to convert a light of a third color (e.g., a blue light) into a light of a first color (e.g., a red light). In some embodiments, a respective first color conversion block of the plurality of first color conversion blocks of a first color CCB1 includes a first matrix MS1, a plurality of first scattering particles SP1 and a plurality of first quantum dots QD1 dispersed in the first matrix MS1. The first matrix MS1 may include a polymer material such as an organic polymer material. Examples of appropriate polymer materials for making the first matrix MS1 include epoxy resins, acrylic resins, polyurethane resins, silicone resins, and silane resins. Examples of appropriate materials for making the plurality of first scattering particles SP1 include TiO₂, ZnO, ZrO₂, Al₂O₃, SiO₂. Examples of appropriate quantum dots materials for making the plurality of first quantum dots QD1 include a quantum dots material of a first color (e.g., a red color). The quantum dots material may include a material selected from a group consisting of CdS, CdSe, ZnSe, InP, PbS, CsPbCl3, CsPbBr3, CsPhI3, CdS/ZnS, CdSe/ZnS, InP/ZnS, PbS/ZnS, CsPbCl3/ZnS, CsPbBr3/ZnS, and CsPhI3/ZnS.

FIG. 6B is a schematic diagram illustrating the structure of a second color conversion block in some embodiments according to the present disclosure. Referring to FIG. 6B, the plurality of second color conversion blocks of a second color CCB2 are color conversion blocks configured to convert a light of a third color (e.g., a blue light) into a light of a second color (e.g., a green light). In some embodiments, a respective second color conversion block of the plurality of second color conversion blocks of a second color CCB2 includes a second matrix MS2, a plurality of second scattering particles SP2 and a plurality of second quantum dots QD2 dispersed in the second matrix MS2. The second matrix MS2 may include a polymer material such as an organic polymer material. Examples of appropriate polymer materials for making the second matrix MS2 include epoxy resins, acrylic resins, polyurethane resins, silicone resins, and silane resins. Examples of appropriate materials for making the plurality of second scattering particles SP2 include TiO₂, ZnO, ZrO₂, Al₂O₃, SiO₂. Examples of appropriate quantum dots materials for making the plurality of second quantum dots QD2 include a quantum dots material of a second color (e.g., a green color). The quantum dots material may include a material selected from a group consisting of CdS, CdSe, ZnSe, InP, PbS, CsPbCl3, CsPbBr3, CsPhI3, CdS/ZnS, CdSe/ZnS, InP/ZnS, PbS/ZnS, CsPbCl3/ZnS, CsPbBr3/ZnS, and CsPhI3/ZnS.

FIG. 6C is a schematic diagram illustrating the structure of a light scattering block in some embodiments according to the present disclosure. Referring to FIG. 6C, a respective light transmissive block of the plurality of light transmissive blocks LTB in some embodiments includes a third matrix MS3 and a plurality of third scattering particles SP3 dispersed in the third matrix MS3. The third matrix MS3 may include a polymer material such as an organic polymer material. Examples of appropriate polymer materials for making the third matrix MS3 include epoxy resins, acrylic resins, polyurethane resins, silicone resins, and silane resins. Examples of appropriate materials for making the plurality of third scattering particles SP3 include TiO₂, ZnO, ZrO₂, Al₂O₃, SiO₂.

In alternative embodiments, the respective light transmissive block of the plurality of light transmissive blocks LTB does not include the plurality of third scattering particles SP3. For example, the respective light scattering block of the plurality of light transmissive blocks LTB includes a substantially transparent insulating material such as the polymer material.

Referring to FIG. 4 and FIG. 5, the display panel in some embodiments includes a first subpixel region SR1 configured to emit light of a first color, a second subpixel region SR2 configured to emit light of a second color, and a third subpixel region SR3 configured to emit light of a third color. Optionally, the first color, the second color, and the third color are three different colors, e.g., three different colors selected from red, green, and blue. Optionally, light of the third color has a wavelength range smaller than a wavelength range of light of the first color, and smaller than a wavelength range of light of the second color. Optionally, light of the second color has a wavelength range smaller than a wavelength range of light of the first color. In one example, the third color is a blue color. In another example, the first color is a red color. In another example, the second color is a green color.

In some embodiments, the first subpixel region SR1 includes a first subpixel first region SR1-1 and a first subpixel second region SR1-2.

Referring to FIG. 4 and FIG. 5, the display panel in some embodiments includes a base substrate BS, a first light-emitting diode LE1, a second light emitting diode LE2, and a third light-emitting diode LE3 on the base substrate BS. The first light-emitting diode LE1 is in the first subpixel region SR1. The second light-emitting diode LE2 is in the second subpixel region SR2. The third light-emitting diode LE3 is in the third subpixel region SR3.

In some embodiments, the first light-emitting diode LE1 includes a first light emitting layer EL1, the second light emitting diode LE2 includes a second light emitting layer EL2, and the third light-emitting diode LE3 includes a third light emitting layer EL3. As shown in FIG. 4 and FIG. 5, in some embodiments, the second light emitting layer EL2 and the third light emitting layer EL3 are spaced apart from each other. In some embodiments, at least a first portion of the first light emitting layer EL1 and the third light emitting layer EL3 are parts of a unitary layer continuously extending from the third subpixel region to at least a first portion of the first subpixel region SR1.

In some embodiments, the display panel includes a cathode extending through the first subpixel region SR1, the second subpixel region SR2, and the third subpixel region SR3. In some embodiments, the display panel further includes one or more common layers extending through the first subpixel region SR1, the second subpixel region SR2, and the third subpixel region SR3. Examples of the one or more common layers include at least one of a hole injection layer, a hole transport layer, an electron barrier layer, a hole barrier layer, an electron transport layer, or an electron injection layer.

In some embodiments, as shown in FIG. 4 and FIG. 5, the first light emitting layer EL1 includes a first portion EL1-1 at least partially in the first subpixel first region SR1-1 and a second portion EL1-2 at least partially in the first subpixel second region SR1-2.

In some embodiments, as shown in FIG. 4 and FIG. 5, the first light-emitting diode LE1 includes two anodes in the first subpixel first region SR1-1 and the first subpixel second region SR1-2, respectively. The two anodes of the first light-emitting diode LE1 are spaced apart by a portion of a pixel definition layer PDL.

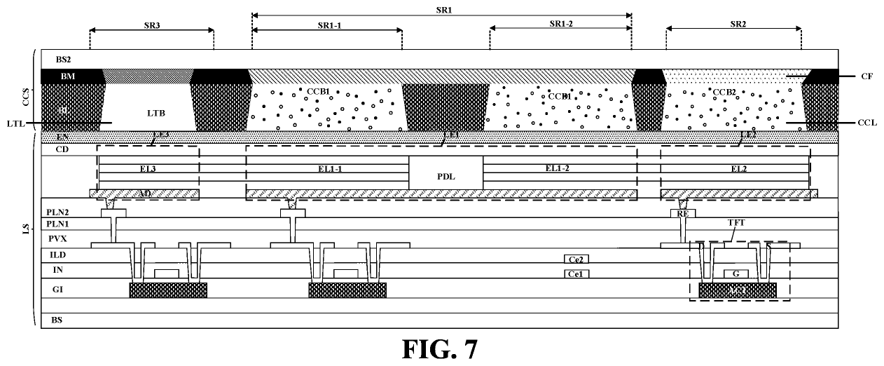

FIG. 7 is a cross-sectional view of a display panel in some embodiments according to the present disclosure. Referring to FIG. 7, the first light-emitting diode LE1 includes a single anode extending at least partially in the first subpixel first region SR1-1 and at least partially in the first subpixel second region SR1-2. A portion of the pixel definition layer PDL is on a side of the single anode away from the base substrate BS. The portion of the pixel definition layer PDL spaces apart the first portion EL1-1 and the second portion EL1-2, which in some embodiments include different emissive materials.

Referring to FIG. 4, FIG. 5, and FIG. 7, in some embodiments an individual light transmissive block of the plurality of light transmissive blocks LTB is at least partially in the third subpixel region SR3. A first individual first color conversion block of the plurality of first color conversion blocks of the first color CCB1 is at least partially in the first subpixel first region SR1-1. Light emitted from the third light-emitting diode LE3 is provided to the individual light transmissive block of the plurality of light transmissive blocks LTB. A first portion of light emitted from the first light-emitting diode LE1 is provided to the first individual first color conversion block of the plurality of first color conversion blocks of a first color CCB1. The light provided to the individual light transmissive block of the plurality of light transmissive blocks LTB and light emitting out of the individual light transmissive block of the plurality of light transmissive blocks LTB are of a same color, e.g., the third color. The first portion of light provided to the first individual first color conversion block of the plurality of first color conversion blocks of a first color CCB1 and light emitting out of the first individual first color conversion block of the plurality of first color conversion blocks of a first color CCB1 are of different colors, e.g., the third color and the first color. The light provided to the individual light transmissive block of the plurality of light transmissive blocks LTB and the portion of light provided to the first individual first color conversion block of the plurality of first color conversion blocks of a first color CCB1 are of a same color, e.g., the third color. Optionally, the first color and the third color are two different colors selected from red, green, and blue. In one example, the third color is a blue color. In another example, the first color is a red color.

Referring to FIG. 4 and FIG. 5, the second light-emitting diode LE2 is configured to provide light to the second subpixel region SR2. Light emitted from the second light-emitting diode LE2 is provided to the individual second color conversion block of the plurality of second color conversion blocks of the second color CCB2. A second portion of light emitted from the first light-emitting diode LE1 is provided to the second individual first color conversion block of the plurality of first color conversion blocks of a first color CCB1. The light provided to the individual second color conversion block of the plurality of second color conversion blocks of the second color CCB2 and light emitting out of the individual second color conversion block of the plurality of second color conversion blocks of the second color CCB2 are of different colors, e.g., the third color and the second color. The second portion of light provided to the second individual first color conversion block of the plurality of first color conversion blocks of a first color CCB1 and light emitting out of the second individual first color conversion block of the plurality of first color conversion blocks of a first color CCB1 are of different colors, e.g., the third color and the first color. The light provided to the individual second color conversion block of the plurality of second color conversion blocks of the second color CCB2 and the second portion of light provided to the second individual first color conversion block of the plurality of first color conversion blocks of a first color CCB1 are of a same color, e.g., the third color. Optionally, the first color, the second color, and the third color are three different colors selected from red, green, and blue. In one example, the third color is a blue color. In another example, the first color is a red color. In another example, the second color is a green color.

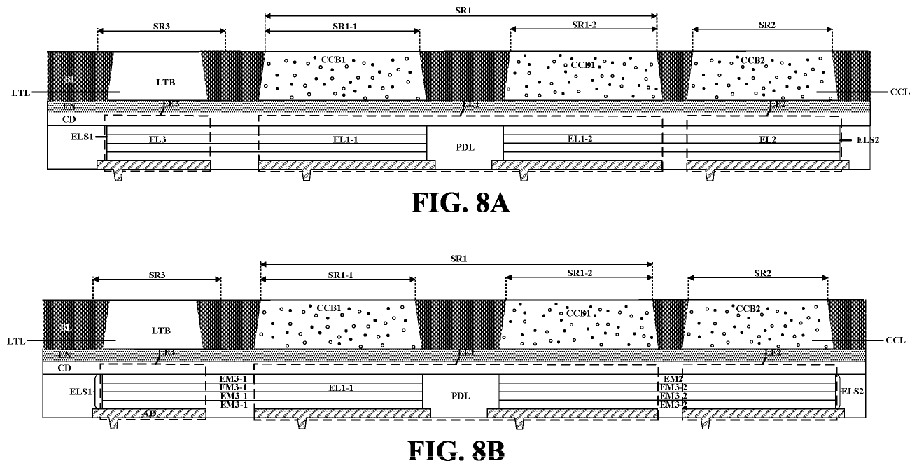

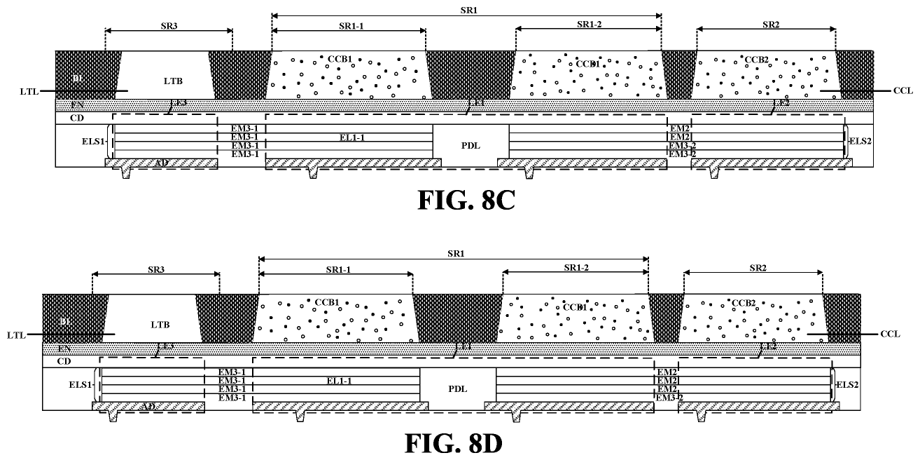

FIG. 8A is a schematic diagram illustrating a first emissive material layer and a second emissive material layer in a display panel in some embodiments according to the present disclosure. Referring to FIG. 8A, in some embodiments, the display panel includes a first emissive material layer ELS1, the first emissive material layer ELS1 including the first portion EL1-1 of the first light emitting layer EL1 and the third light emitting layer EL3. For example, the first portion EL1-1 of the first light emitting layer EL1 and the third light emitting layer EL3 are parts of a first emissive material layer ELS1. Optionally, the first portion EL1-1 of the first light emitting layer EL1 and the third light emitting layer EL3 include a same light emitting material. For example, the first portion EL1-1 of the first light emitting layer EL1 and the third light emitting layer EL3 have a same composition.

In some embodiments, an orthographic projection of the first emissive material layer ELS1 on a base substrate BS at least partially overlaps with an orthographic projection of the individual light transmissive block of the plurality of light transmissive blocks LTB in the third subpixel region SR3 on the base substrate BS, and at least partially overlaps with an orthographic projection of the first individual first color conversion block of the plurality of first color conversion blocks of a first color CCB1 in the first subpixel first region SR1-1 on the base substrate BS. Optionally, the orthographic projection of the first emissive material layer ELS1 on the base substrate BS at least partially overlaps with an orthographic projection of a portion of the bank layer BL spacing apart the individual light transmissive block and the first individual first color conversion block on the base substrate BS.

Referring to FIG. 4 and FIG. 5, an individual second color conversion block of the plurality of second color conversion blocks of the second color CCB2 is at least partially in the second subpixel region SR2. A second individual first color conversion block of the plurality of first color conversion blocks of a first color CCB1 is at least partially in the first subpixel second region SR1-2.

Referring to FIG. 8A, in some embodiments, the display panel includes a second emissive material layer ELS2, the second emissive material layer ELS2 including the second portion EL1-2 of the first light emitting layer EL1 and the second light emitting layer EL2. For example, the second portion EL1-2 of the first light emitting layer EL1 and the second light emitting layer EL2 are parts of a second emissive material layer ELS2. Optionally, the second portion EL1-2 of the first light emitting layer EL1 and the second light emitting layer EL2 include a same light emitting material. For example, the second portion EL1-2 of the first light emitting layer EL1 and the second light emitting layer EL2 have a same composition.

In some embodiments, an orthographic projection of the second emissive material layer ELS2 on a base substrate BS at least partially overlaps with an orthographic projection of the individual second color conversion block of the plurality of second color conversion blocks of the second color CCB2 in the second subpixel region SR2 on the base substrate BS, and at least partially overlaps with an orthographic projection of the second individual first color conversion block of the plurality of first color conversion blocks of a first color CCB1 in the first subpixel second region SR1-2 on the base substrate BS. Optionally, the orthographic projection of the second emissive material layer ELS2 on the base substrate BS at least partially overlaps with an orthographic projection of a portion of the bank layer BL spacing apart the individual second color conversion block and the second individual first color conversion block on the base substrate BS.

In some embodiments, the first subpixel first region SR1-1 and the first subpixel second region SR1-2 are parts of a first subpixel region SR1 in a pixel. For example, the first subpixel first region SR1-1 and the first subpixel second region SR1-2 in combination are configured to provide light of the first color in the pixel. Optionally, the pixel includes a first subpixel region SR1, the second subpixel region SR2, and the third subpixel region SR3. In one example, the first subpixel first region SR1-1 and the first subpixel second region SR1-2 are adjacent to each other. In an alternative example, the first subpixel first region SR1-1 and the first subpixel second region SR1-2 are spaced apart by the second subpixel region SR2, or by the third subpixel region SR3.

Each of the first emissive material layer ELS1 and the second emissive material layer ELS2 may have a single layer structure or a multiple layer structure. Referring to FIG. 8A, each of the first emissive material layer ELS1 and the second emissive material layer ELS2 has a multiple layer structure. In alternative embodiments, at least one of the first emissive material layer ELS1 and the second emissive material layer ELS2 has a single layer structure.

In some embodiments, the first emissive material layer ELS1 includes multiple first emissive material sub-layers. In some embodiments, at least two of the multiple first emissive material sub-layers are emissive material sub-layers of a same color, e.g., of a third color. In one example, the multiple first emissive material sub-layers are all emissive material sub-layers of a same color, e.g., of a third color.

In alternative embodiments, at least two of the multiple first emissive material sub-layers are emissive material sub-layers of different colors, e.g., of a third color and a first color.

In some embodiments, the second emissive material layer ELS2 includes multiple second emissive material sub-layers. In some embodiments, at least two of the multiple second emissive material sub-layers are emissive material sub-layers of a same color, e.g., of a third color. In one example, the multiple second emissive material sub-layers are all emissive material sub-layers of a same color, e.g., of a third color.

In alternative embodiments, at least two of the multiple second emissive material sub-layers are emissive material sub-layers of different colors, e.g., of a third color and a second color.

FIG. 8B is a schematic diagram illustrating a first emissive material layer and a second emissive material layer in a display panel in some embodiments according to the present disclosure. Referring to FIG. 8B, the first emissive material layer ELS1 in some embodiments includes a stacked structure comprising one or more first emissive material sub-layers of a third color EM3-1. A total number of the one or more first emissive material sub-layers of the third color EM3-1 in the stacked structure is equal to or greater than two, e.g., 2, 3, 4, or 5. In one example depicted in FIG. 8B, a total number of the one or more first emissive material sub-layers of the third color EM3-1 in the stacked structure is four. Optionally, each of the one or more first emissive material sub-layers of a third color EM3-1 extends from the third subpixel region SR3 to the first subpixel first region SR1-1. Optionally, each of the one or more first emissive material sub-layers of a third color EM3-1 includes a portion of the third light emitting layer EL3 and a portion of the first portion EL1-1 of the first light emitting layer EL1 as denoted in FIG. 4, FIG. 5, and FIG. 7.

In some embodiments, the second emissive material layer ELS2 include a stacked structure comprising one or more second emissive material sub-layers of a third color EM3-2. A total number of the one or more second emissive material sub-layers of the third color EM3-2 in the stacked structure is equal to or greater than two, e.g., 2, 3, 4, or 5. In one example depicted in FIG. 7, a total number of the one or more second emissive material sub-layers of the third color EM3-2 in the stacked structure is three. Optionally, each of the one or more second emissive material sub-layers of a third color EM3-2 extends from the first subpixel second region SR1-2 to the second subpixel region SR2. Optionally, each of the one or more second emissive material sub-layers of a third color EM3-2 includes a portion of the second portion EL1-2 of the first light emitting layer EL1 and a portion of the second light emitting layer EL2 as denoted in FIG. 4, FIG. 5, and FIG. 7.

In some embodiments, the one or more first emissive material sub-layers of the third color EM3-1 are configured to emit light of the third color in a first wavelength range, and the one or more second emissive material sub-layers of the third color EM3-2 are configured to emit light of the third color in a second wavelength range.

In some embodiments, the first wavelength range is different from the second wavelength range.

In alternative embodiments, the first wavelength range is the same as the second wavelength range.

In some embodiments, the one or more first emissive material sub-layers of the third color EM3-1 are configured to emit light of the third color with a first peak wavelength, and the one or more second emissive material sub-layers of the third color EM3-2 are configured to emit light of the third color with a second peak wavelength. Optionally, both the first peak wavelength and the second peak wavelength are in a wavelength range of blue light, e.g., 380 nm to 500 nm.

In some embodiments, the first peak wavelength is different from the second peak wavelength. Optionally, the first peak wavelength differs from the second peak wavelength by at least 0.1% (e.g., by at least 0.2%, by at least 0.3%, by at least 0.4%, by at least 0.5%, by at least 0.6%, by at least 0.7%, by at least 0.8%, by at least 0.9%, by at least 1.0%, by at least 1.1%, by at least 1.2%, by at least 1.3%, by at least 1.4%, by at least 1.5%, by at least 1.6%, by at least 1.7%, by at least 1.8%, by at least 1.9%, by at least 2.0%, by at least 2.1%, or by at least 2.2%) of the second peak wavelength. In one example, the first peak wavelength is greater than the second peak wavelength. In an alternative example, the second peak wavelength is greater than the first peak wavelength.

In alternative embodiments, the first peak wavelength is the same as the second peak wavelength.

In one example, the first peak wavelength is in a range of 460 nm to 463 nm. In another example, the second peak wavelength is in a range of 450 nm to 454 nm.

In some embodiments, the stacked structure of the second emissive material layer ELS2 further include at least one emissive material sub-layer of the second color EM2. Optionally, the at least one emissive material sub-layer of the second color EM2 is on a side of the one or more second emissive material sub-layers of the third color EM3-2 closer to the individual second color conversion block of the plurality of second color conversion blocks of the second color CCB2 in the second subpixel region SR2. Optionally, the at least one emissive material sub-layer of the second color EM2 is configured to emit light of the second color. Optionally, the at least one emissive material sub-layer of the second color EM2 is configured to emit green light having a peak wavelength in a range of 528 nm to 532 nm. Referring to FIG. 8B, a total number of the one or more second emissive material sub-layers of the third color EM3-2 in the stacked structure of the second emissive material layer ELS2 is three, and a total number of the at least one emissive material sub-layer of the second color EM2 in the stacked structure of the second emissive material layer ELS2 is one.

FIG. 8C is a schematic diagram illustrating a first emissive material layer and a second emissive material layer in a display panel in some embodiments according to the present disclosure. Referring to FIG. 8C, a total number of the one or more second emissive material sub-layers of the third color EM3-2 in the stacked structure of the second emissive material layer ELS2 is two, and a total number of the at least one emissive material sub-layer of the second color EM2 in the stacked structure of the second emissive material layer ELS2 is two.

FIG. 8D is a schematic diagram illustrating a first emissive material layer and a second emissive material layer in a display panel in some embodiments according to the present disclosure. Referring to FIG. 8D, a total number of the one or more second emissive material sub-layers of the third color EM3-2 in the stacked structure of the second emissive material layer ELS2 is one, and a total number of the at least one emissive material sub-layer of the second color EM2 in the stacked structure of the second emissive material layer ELS2 is three.

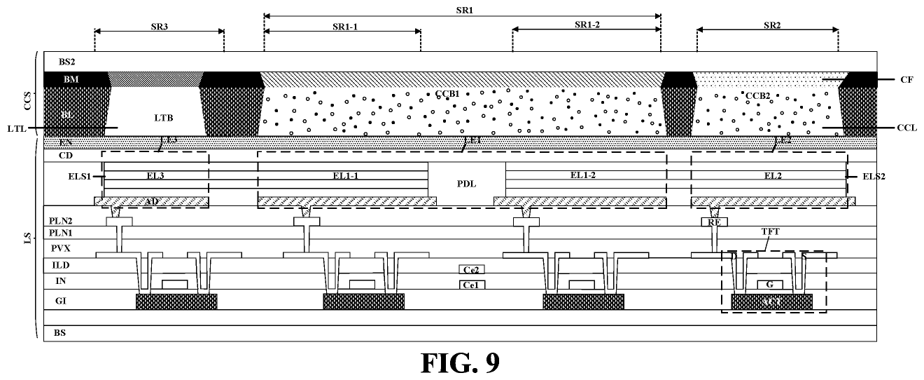

FIG. 9 is a cross-sectional view of a display panel in some embodiments according to the present disclosure. FIG. 9 may be a cross-sectional, for example, along a B-B′ line in FIG. 3. Referring to FIG. 9, the display panel in some embodiments includes a light emitting substrate LS and a color conversion substrate CCS on the light emitting substrate LS. In some embodiments, the color conversion substrate CCS includes a second base substrate BS2, a bank layer BL on the second base substrate BS2 defining a plurality of apertures, a color conversion layer CCL and a light transmissive layer LTL at least partially in the plurality of apertures defined by the bank layer BL. In some embodiments, the color conversion layer CCL includes a plurality of color conversion blocks, e.g., a plurality of first color conversion blocks of a first color CCB1 and a plurality of second color conversion blocks of a second color CCB2. The light transmissive layer LTL includes a plurality of light transmissive blocks LTB. In some embodiments, the light transmissive layer LTL is absent of color conversion materials such as quantum dots materials. The plurality of light transmissive blocks LTB are absent of color conversion materials such as quantum dots materials. As shown in FIG. 9, the light transmissive layer LTL (including the plurality of light transmissive blocks LTB) includes a substantially transparent insulating material.

Referring to FIG. 9, the display panel in some embodiments includes a first light-emitting diode LE1 configured to provide light to the first subpixel region SR1, a second light-emitting diode LE2 configured to provide light to the second subpixel region SR2, and a third light-emitting diode LE3 configured to provide light to the third subpixel region SR3. A first portion of light emitted from the first light-emitting diode LE1 is provided to a first portion of the first individual first color conversion block of the plurality of first color conversion blocks of a first color CCB1. A second portion of light emitted from the first light-emitting diode LE1 is provided to a second portion of the first individual first color conversion block of the plurality of first color conversion blocks of a first color CCB1. Light emitted from the third light-emitting diode LE3 is provided to the individual light transmissive block of the plurality of light transmissive blocks LTB. The light provided to the individual light transmissive block of the plurality of light transmissive blocks LTB and light emitting out of the individual light transmissive block of the plurality of light transmissive blocks LTB are of a same color, e.g., the third color. The first portion of light provided to the first portion of the first individual first color conversion block of the plurality of first color conversion blocks of a first color CCB1 and light emitting out of the first individual first color conversion block of the plurality of first color conversion blocks of a first color CCB1 are of different colors, e.g., the third color and the first color. The light provided to the individual light transmissive block of the plurality of light transmissive blocks LTB and the portion of light provided to the first individual first color conversion block of the plurality of first color conversion blocks of a first color CCB1 are of a same color, e.g., the third color. Optionally, the first color and the third color are two different colors selected from red, green, and blue. In one example, the third color is a blue color. In another example, the first color is a red color.

Referring to FIG. 9, an individual second color conversion block of the plurality of second color conversion blocks of the second color CCB2 is at least partially in the second subpixel region SR2. The first individual first color conversion block of the plurality of first color conversion blocks of the first color CCB1 is at least partially in the first subpixel second region SR1-2. For example, a second portion of the first individual first color conversion block of the plurality of first color conversion blocks of the first color CCB1 is at least partially in the first subpixel second region SR1-2.

Referring to FIG. 9, the second light-emitting diode LE2 is configured to provide light to the second subpixel region SR2. Light emitted from the second light-emitting diode LE2 is provided to the individual second color conversion block of the plurality of second color conversion blocks of the second color CCB2. A second portion of light emitted from the first light-emitting diode LE1 is provided to the second portion of the first individual first color conversion block of the plurality of first color conversion blocks of a first color CCB1. The light provided to the individual second color conversion block of the plurality of second color conversion blocks of the second color CCB2 and light emitting out of the individual second color conversion block of the plurality of second color conversion blocks of the second color CCB2 are of different colors, e.g., the third color and the second color. The second portion of light provided to the second portion of the first individual first color conversion block of the plurality of first color conversion blocks of a first color CCB1 and light emitting out of the second portion of the first individual first color conversion block of the plurality of first color conversion blocks of a first color CCB1 are of different colors, e.g., the third color and the first color. The light provided to the individual second color conversion block of the plurality of second color conversion blocks of the second color CCB2 and the second portion of light provided to the second individual first color conversion block of the plurality of first color conversion blocks of a first color CCB1 are of a same color, e.g., the third color. Optionally, the first color, the second color, and the third color are three different colors selected from red, green, and blue. In one example, the third color is a blue color. In another example, the first color is a red color. In another example, the second color is a green color.

In some embodiments, the display panel includes a first emissive material layer ELS1, the first emissive material layer ELS1 including the first portion EL1-1 of the first light emitting layer EL1 and the third light emitting layer EL3. For example, the first portion EL1-1 of the first light emitting layer EL1 and the third light emitting layer EL3 are parts of a first emissive material layer ELS1. Optionally, the first portion EL1-1 of the first light emitting layer EL1 and the third light emitting layer EL3 include a same light emitting material. For example, the first portion EL1-1 of the first light emitting layer EL1 and the third light emitting layer EL3 have a same composition.

In some embodiments, an orthographic projection of the first emissive material layer ELS1 on a base substrate BS at least partially overlaps with an orthographic projection of the individual light transmissive block of the plurality of light transmissive blocks LTB in the third subpixel region SR3 on the base substrate BS, and at least partially overlaps with an orthographic projection of the first individual first color conversion block of the plurality of first color conversion blocks of a first color CCB1 in the first subpixel first region SR1-1 on the base substrate BS. Optionally, the orthographic projection of the first emissive material layer ELS1 on the base substrate BS at least partially overlaps with an orthographic projection of a portion of the bank layer BL spacing apart the individual light transmissive block and the first individual first color conversion block on the base substrate BS.

Referring to FIG. 8A, in some embodiments, the display panel includes a second emissive material layer ELS2, the second emissive material layer ELS2 including the second portion EL1-2 of the first light emitting layer EL1 and the second light emitting layer EL2. For example, the second portion EL1-2 of the first light emitting layer EL1 and the second light emitting layer EL2 are parts of a second emissive material layer ELS2. Optionally, the second portion EL1-2 of the first light emitting layer EL1 and the second light emitting layer EL2 include a same light emitting material. For example, the second portion EL1-2 of the first light emitting layer EL1 and the second light emitting layer EL2 have a same composition.

In some embodiments, an orthographic projection of the second emissive material layer ELS2 on a base substrate BS at least partially overlaps with an orthographic projection of the individual second color conversion block of the plurality of second color conversion blocks of the second color CCB2 in the second subpixel region SR2 on the base substrate BS, and at least partially overlaps with an orthographic projection of the second individual first color conversion block of the plurality of first color conversion blocks of a first color CCB1 in the first subpixel second region SR1-2 on the base substrate BS. Optionally, the orthographic projection of the second emissive material layer ELS2 on the base substrate BS at least partially overlaps with an orthographic projection of a portion of the bank layer BL spacing apart the individual second color conversion block and the second individual first color conversion block on the base substrate BS.

In some embodiments, the first subpixel first region SR1-1 and the first subpixel second region SR1-2 are parts of a first subpixel region SR1 in a pixel. For example, the first subpixel first region SR1-1 and the first subpixel second region SR1-2 in combination are configured to provide light of the first color in the pixel. Optionally, the pixel includes a first subpixel region SR1, the second subpixel region SR2, and the third subpixel region SR3. In one example, the first subpixel first region SR1-1 and the first subpixel second region SR1-2 are adjacent to each other. In an alternative example, the first subpixel first region SR1-1 and the first subpixel second region SR1-2 are spaced apart by the second subpixel region SR2, or by the third subpixel region SR3.

Each of the first emissive material layer ELS1 and the second emissive material layer ELS2 may have a single layer structure or a multiple layer structure. Referring to FIG. 8A, each of the first emissive material layer ELS1 and the second emissive material layer ELS2 has a multiple layer structure. In alternative embodiments, at least one of the first emissive material layer ELS1 and the second emissive material layer ELS2 has a single layer structure.

In some embodiments, the first emissive material layer ELS1 includes multiple first emissive material sub-layers. In some embodiments, at least two of the multiple first emissive material sub-layers are emissive material sub-layers of a same color, e.g., of a third color. In one example, the multiple first emissive material sub-layers are all emissive material sub-layers of a same color, e.g., of a third color.

In alternative embodiments, at least two of the multiple first emissive material sub-layers are emissive material sub-layers of different colors, e.g., of a third color and a first color.

In some embodiments, the second emissive material layer ELS2 includes multiple second emissive material sub-layers. In some embodiments, at least two of the multiple second emissive material sub-layers are emissive material sub-layers of a same color, e.g., of a third color. In one example, the multiple second emissive material sub-layers are all emissive material sub-layers of a same color, e.g., of a third color.

In alternative embodiments, at least two of the multiple second emissive material sub-layers are emissive material sub-layers of different colors, e.g., of a third color and a second color.

Referring to FIG. 9, in some embodiments, the first individual first color conversion block of the plurality of first color conversion blocks of a first color CCB1 extends over the first subpixel first region SR1-1 and the first subpixel second region SR1-2. In some embodiments, an orthographic projection of the first individual first color conversion block of the plurality of first color conversion blocks of a first color CCB1 on a base substrate BS at least partially overlaps with an orthographic projection of the first emissive material layer ELS1 on a base substrate BS, and at least partially overlaps with an orthographic projection of the second emissive material layer ELS2 on the base substrate BS. Optionally, the orthographic projection of the first individual first color conversion block of the plurality of first color conversion blocks of a first color CCB1 on the base substrate BS at least partially overlaps with an orthographic projection of a portion of the pixel definition layer PDL spacing apart the first emissive material layer ELS1 and the second emissive material layer ELS2 on the base substrate BS.

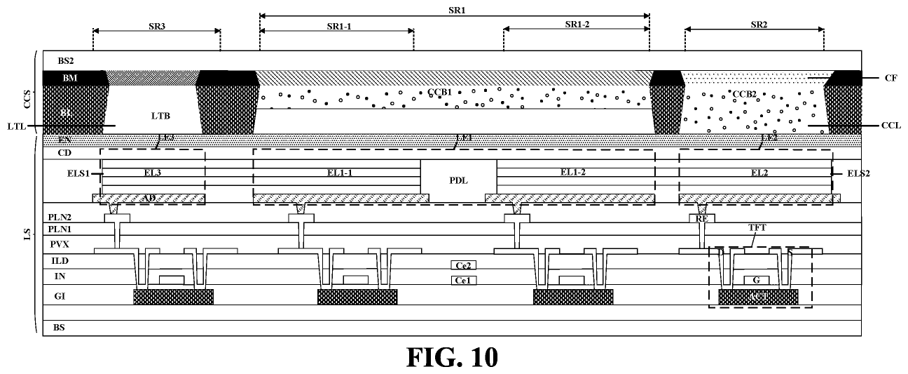

FIG. 10 is a cross-sectional view of a display panel in some embodiments according to the present disclosure. The display panel depicted in FIG. 10 differs from the display panel depicted in FIG. 9 in that, in the display panel depicted in FIG. 10, the first individual first color conversion block of the plurality of first color conversion blocks of the first color CCB1 has a thickness smaller than a thickness of the individual second color conversion block of the plurality of second color conversion blocks of the second color CCB2. Optionally, the thickness of the first individual first color conversion block of the plurality of first color conversion blocks of the first color CCB1 is less than 80% (less than 75%, less than 70%, less than 65%, less than 60%, less than 55%, less than 50%, less than 45%, or less than 40%) of the thickness of the individual second color conversion block of the plurality of second color conversion blocks of the second color CCB2. Optionally, in a cross-section along a plane perpendicular to the base substrate BS and intersecting the individual light transmissive block of the plurality of light transmissive blocks LTB, the first individual first color conversion block of the plurality of first color conversion blocks of the first color CCB1, and the individual second color conversion block of the plurality of second color conversion blocks of the second color CCB2, a width of the first individual first color conversion block of the plurality of first color conversion blocks of the first color CCB1 is substantially the same as twice of a width of the individual second color conversion block of the plurality of second color conversion blocks of the second color CCB2. As used herein, the term “substantially the same” refers to a difference between two values not exceeding 10% of a base value (e.g., one of the two values), e.g., not exceeding 8%, not exceeding 6%, not exceeding 4%, not exceeding 2%, not exceeding 1%, not exceeding 0.5%, not exceeding 0.1%, not exceeding 0.05%, and not exceeding 0.01%, of the base value.

Referring to FIG. 9, in some embodiments, a thickness of the first individual first color conversion block of the plurality of first color conversion blocks of the first color CCB1 is substantially the same as a thickness of the individual second color conversion block of the plurality of second color conversion blocks of the second color CCB2. Optionally, in a cross-section along a plane perpendicular to the base substrate BS and intersecting the individual light transmissive block of the plurality of light transmissive blocks LTB, the first individual first color conversion block of the plurality of first color conversion blocks of the first color CCB1, and the individual second color conversion block of the plurality of second color conversion blocks of the second color CCB2, a width of the first individual first color conversion block of the plurality of first color conversion blocks of the first color CCB1 is substantially the same as twice of a width of the individual second color conversion block of the plurality of second color conversion blocks of the second color CCB2.

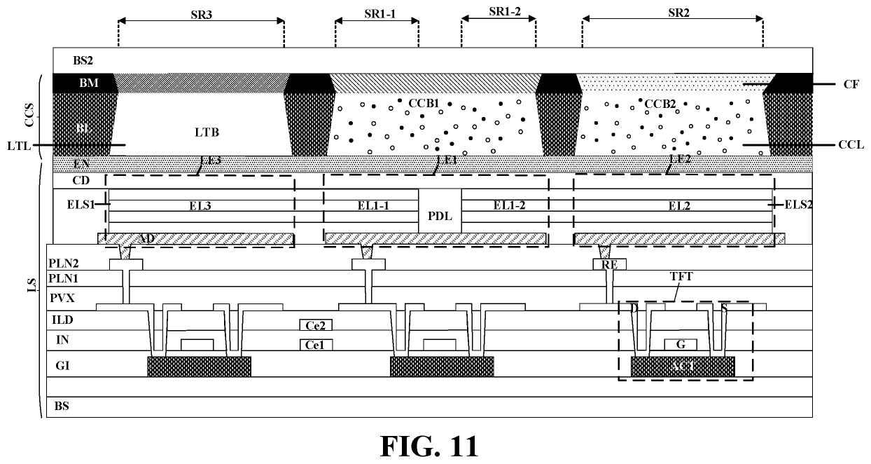

FIG. 11 is a cross-sectional view of a display panel in some embodiments according to the present disclosure. Referring to FIG. 11, in some embodiments, a thickness of the first individual first color conversion block of the plurality of first color conversion blocks of the first color CCB1 is substantially the same as a thickness of the individual second color conversion block of the plurality of second color conversion blocks of the second color CCB2. Optionally, in a cross-section along a plane perpendicular to the base substrate BS and intersecting the individual light transmissive block of the plurality of light transmissive blocks LTB, the first individual first color conversion block of the plurality of first color conversion blocks of the first color CCB1, and the individual second color conversion block of the plurality of second color conversion blocks of the second color CCB2, a width of the first individual first color conversion block of the plurality of first color conversion blocks of the first color CCB1 is substantially the same as a width of the individual second color conversion block of the plurality of second color conversion blocks of the second color CCB2.

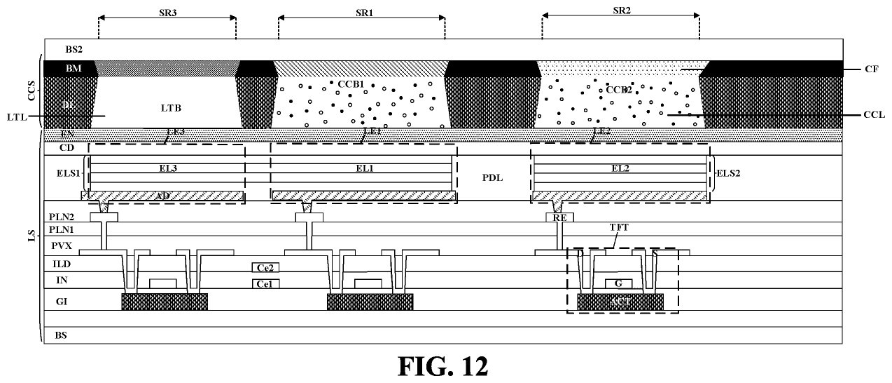

Various appropriate implementations may be practiced in the present disclosure. FIG. 12 is a cross-sectional view of a display panel in some embodiments according to the present disclosure. Referring to FIG. 12, the display panel in some embodiments includes a light emitting substrate LS and a color conversion substrate CCS on the light emitting substrate LS. In some embodiments, the color conversion substrate CCS includes a second base substrate BS2, a bank layer BL on the second base substrate BS2 defining a plurality of apertures, a color conversion layer CCL and a light transmissive layer LTL at least partially in the plurality of apertures defined by the bank layer BL. In some embodiments, the color conversion layer CCL includes a plurality of color conversion blocks, e.g., a plurality of first color conversion blocks of a first color CCB1 and a plurality of second color conversion blocks of a second color CCB2. The light transmissive layer LTL includes a plurality of light transmissive blocks LTB.

In some embodiments, the light transmissive layer LTL is absent of color conversion materials such as quantum dots materials. The plurality of light transmissive blocks LTB are absent of color conversion materials such as quantum dots materials. As shown in FIG. 12, the light transmissive layer LTL (including the plurality of light transmissive blocks LTB) includes a substantially transparent insulating material.

Referring to FIG. 12, the display panel in some embodiments includes a first subpixel region SR1 configured to emit light of a first color, a second subpixel region SR2 configured to emit light of a second color, and a third subpixel region SR3 configured to emit light of a third color. Optionally, the first color, the second color, and the third color are three different colors, e.g., three different colors selected from red, green, and blue. In one example, the third color is a blue color. In another example, the first color is a red color. In another example, the second color is a green color.

Referring to FIG. 12, the display panel in some embodiments includes a base substrate BS, a first light-emitting diode LE1, a second light emitting diode LE2, and a third light-emitting diode LE3 on the base substrate BS. The first light-emitting diode LE1 is in the first subpixel region SR1. The second light-emitting diode LE2 is in the second subpixel region SR2. The third light-emitting diode LE3 is in the third subpixel region SR3.

In some embodiments, the first light-emitting diode LE1 includes a first light emitting layer EL1, the second light emitting diode LE2 includes a second light emitting layer EL2, and the third light-emitting diode LE3 includes a third light emitting layer EL3. As shown in FIG. 12, in some embodiments, the second light emitting layer EL2 and the third light emitting layer EL3 are spaced apart from each other. In some embodiments, the first light emitting layer EL1 and the third light emitting layer EL3 are parts of a unitary layer continuously extending from the third subpixel region to at least a first portion of the first subpixel region SR1.

In some embodiments, the display panel includes a cathode extending through the first subpixel region SR1, the second subpixel region SR2, and the third subpixel region SR3. In some embodiments, the display panel further includes one or more common layers extending through the first subpixel region SR1, the second subpixel region SR2, and the third subpixel region SR3. Examples of the one or more common layers include at least one of a hole injection layer, a hole transport layer, an electron barrier layer, a hole barrier layer, an electron transport layer, or an electron injection layer.

Referring to FIG. 12, in some embodiments, an individual light transmissive block of the plurality of light transmissive blocks LTB is at least partially in the third subpixel region SR3. A first individual first color conversion block of the plurality of first color conversion blocks of the first color CCB1 is at least partially in the first subpixel region SR1. Light emitted from the third light-emitting diode LE3 is provided to the individual light transmissive block of the plurality of light transmissive blocks LTB. Light emitted from the first light-emitting diode LE1 is provided to the first individual first color conversion block of the plurality of first color conversion blocks of a first color CCB1. The light provided to the individual light transmissive block of the plurality of light transmissive blocks LTB and light emitting out of the individual light transmissive block of the plurality of light transmissive blocks LTB are of a same color, e.g., the third color. The light provided to the first individual first color conversion block of the plurality of first color conversion blocks of a first color CCB1 and light emitting out of the first individual first color conversion block of the plurality of first color conversion blocks of a first color CCB1 are of different colors, e.g., the third color and the first color. The light provided to the individual light transmissive block of the plurality of light transmissive blocks LTB and the light provided to the first individual first color conversion block of the plurality of first color conversion blocks of a first color CCB1 are of a same color, e.g., the third color. Optionally, the first color and the third color are two different colors selected from red, green, and blue. In one example, the third color is a blue color. In another example, the first color is a red color.

Referring to FIG. 12, the display panel in some embodiments includes a second subpixel region SR2 configured to emit light of a second color. An individual second color conversion block of the plurality of second color conversion blocks of the second color CCB2 is at least partially in the second subpixel region SR2.

Referring to FIG. 12, the second light-emitting diode LE2 is configured to provide light to the second subpixel region SR2. Light emitted from the second light-emitting diode LE2 is provided to the individual second color conversion block of the plurality of second color conversion blocks of the second color CCB2. The light provided to the individual second color conversion block of the plurality of second color conversion blocks of the second color CCB2 and light emitting out of the individual second color conversion block of the plurality of second color conversion blocks of the second color CCB2 are of different colors, e.g., the third color and the second color. Optionally, the second color and the third color are two different colors selected from red, green, and blue. In one example, the third color is a blue color. In another example, the second color is a green color.

In some embodiments, the display panel includes a first emissive material layer ELS1, the first emissive material layer ELS1 including at least a portion of the first light emitting layer EL1 and the third light emitting layer EL3. For example, the at least a portion of the first light emitting layer EL1 and the third light emitting layer EL3 are parts of a first emissive material layer ELS1. Optionally, the at least a portion of the first light emitting layer EL1 and the third light emitting layer EL3 include a same light emitting material. For example, the first light emitting layer EL1 and the third light emitting layer EL3 have a same composition.

In some embodiments, the display panel includes a second emissive material layer ELS2, the second emissive material layer ELS2 including the second light emitting layer EL2.

In some embodiments, an orthographic projection of the first emissive material layer ELS1 on a base substrate BS at least partially overlaps with an orthographic projection of the individual light transmissive block of the plurality of light transmissive blocks LTB in the third subpixel region SR3 on the base substrate BS, and at least partially overlaps with an orthographic projection of the first individual first color conversion block of the plurality of first color conversion blocks of a first color CCB1 in the first subpixel region SR1 on the base substrate BS. Optionally, the orthographic projection of the first emissive material layer ELS1 on the base substrate BS at least partially overlaps with an orthographic projection of a portion of the bank layer BL spacing apart the individual light transmissive block and the first individual first color conversion block on the base substrate BS.

In some embodiments, an orthographic projection of the second emissive material layer ELS2 on a base substrate BS at least partially overlaps with an orthographic projection of the individual second color conversion block of the plurality of second color conversion blocks of the second color CCB2 in the second subpixel region SR2 on the base substrate BS.

In some embodiments, the first subpixel region SRI the second subpixel region SR2, and the third subpixel region SR3 are subpixel regions in a same pixel.

In some embodiments, the first emissive material layer ELS1 includes multiple first emissive material sub-layers. In some embodiments, at least two of the multiple first emissive material sub-layers are emissive material sub-layers of a same color, e.g., of a third color. In one example, the multiple first emissive material sub-layers are all emissive material sub-layers of a same color, e.g., of a third color.

In alternative embodiments, at least two of the multiple first emissive material sub-layers are emissive material sub-layers of different colors, e.g., of a third color and a first color.

In some embodiments, the second emissive material layer ELS2 includes multiple second emissive material sub-layers. In some embodiments, at least two of the multiple second emissive material sub-layers are emissive material sub-layers of a same color, e.g., of a third color. In one example, the multiple second emissive material sub-layers are all emissive material sub-layers of a same color, e.g., of a third color.

In alternative embodiments, at least two of the multiple second emissive material sub-layers are emissive material sub-layers of different colors, e.g., of a third color and a second color.

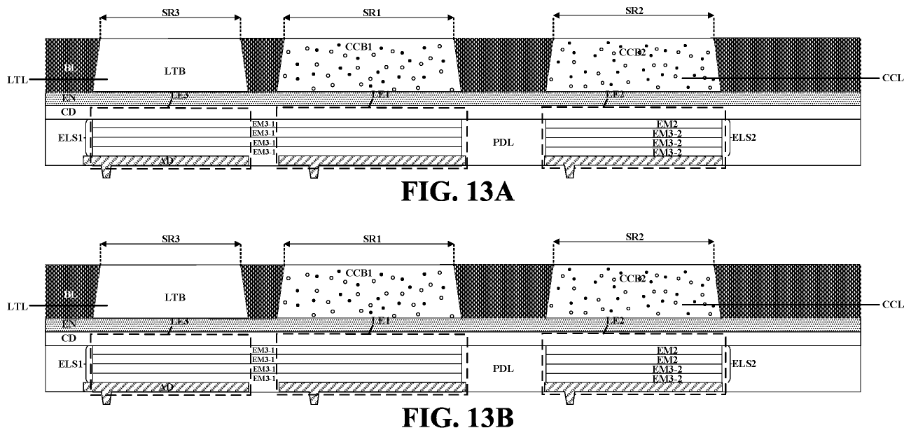

FIG. 13A is a schematic diagram illustrating a first emissive material layer and a second emissive material layer in a display panel in some embodiments according to the present disclosure. Referring to FIG. 13A, the first emissive material layer ELS1 in some embodiments includes a stacked structure comprising one or more first emissive material sub-layers of a third color EM3-1. A total number of the one or more first emissive material sub-layers of the third color EM3-1 in the stacked structure is equal to or greater than two, e.g., 2, 3, 4, or 5. In one example depicted in FIG. 15, a total number of the one or more first emissive material sub-layers of the third color EM3-1 in the stacked structure is four. Optionally, each of the one or more first emissive material sub-layers of a third color EM3-1 extends from the third subpixel region SR3 to the first subpixel first region SR1-1. Optionally, each of the one or more first emissive material sub-layers of a third color EM3-1 includes a portion of the third light emitting layer EL3 and a portion of the first light emitting layer EL1 as denoted in FIG. 12.

In some embodiments, the second emissive material layer ELS2 include a stacked structure comprising one or more second emissive material sub-layers of a third color EM3-2. A total number of the one or more second emissive material sub-layers of the third color EM3-2 in the stacked structure is equal to or greater than two, e.g., 2, 3, 4, or 5. In one example depicted in FIG. 15, a total number of the one or more second emissive material sub-layers of the third color EM3-2 in the stacked structure is three.

In some embodiments, the one or more first emissive material sub-layers of the third color EM3-1 are configured to emit light of the third color in a first wavelength range, and the one or more second emissive material sub-layers of the third color EM3-2 are configured to emit light of the third color in a second wavelength range.

In some embodiments, the first wavelength range is different from the second wavelength range.

In alternative embodiments, the first wavelength range is the same as the second wavelength range.

In some embodiments, the one or more first emissive material sub-layers of the third color EM3-1 are configured to emit light of the third color with a first peak wavelength, and the one or more second emissive material sub-layers of the third color EM3-2 are configured to emit light of the third color with a second peak wavelength. Optionally, both the first peak wavelength and the second peak wavelength are in a wavelength range of blue light, e.g., 380 nm to 500 nm.

In some embodiments, the first peak wavelength is different from the second peak wavelength. Optionally, the first peak wavelength differs from the second peak wavelength by at least 0.1% (e.g., by at least 0.2%, by at least 0.3%, by at least 0.4%, by at least 0.5%, by at least 0.6%, by at least 0.7%, by at least 0.8%, by at least 0.9%, by at least 1.0%, by at least 1.1%, by at least 1.2%, by at least 1.3%, by at least 1.4%, by at least 1.5%, by at least 1.6%, by at least 1.7%, by at least 1.8%, by at least 1.9%, by at least 2.0%, by at least 2.1%, or by at least 2.2%) of the second peak wavelength. In one example, the first peak wavelength is greater than the second peak wavelength. In an alternative example, the second peak wavelength is greater than the first peak wavelength.

In alternative embodiments, the first peak wavelength is the same as the second peak wavelength.

In one example, the first peak wavelength is in a range of 460 nm to 463 nm. In another example, the second peak wavelength is in a range of 450 nm to 454 nm.

In some embodiments, the stacked structure of the second emissive material layer ELS2 further include at least one emissive material sub-layer of the second color EM2. Optionally, the at least one emissive material sub-layer of the second color EM2 is on a side of the second emissive material sub-layers of the third color EM3-2 closer to the individual second color conversion block of the plurality of second color conversion blocks of the second color CCB2 in the second subpixel region SR2. Optionally, the at least one emissive material sub-layer of the second color EM2 is configured to emit light of the second color. Optionally, the at least one emissive material sub-layer of the second color EM2 is configured to emit green light having a peak wavelength in a range of 528 nm to 532 nm. Referring to FIG. 13A, a total number of the one or more second emissive material sub-layers of the third color EM3-2 in the stacked structure of the second emissive material layer ELS2 is three, and a total number of the at least one emissive material sub-layer of the second color EM2 in the stacked structure of the second emissive material layer ELS2 is one.

FIG. 13B is a schematic diagram illustrating a first emissive material layer and a second emissive material layer in a display panel in some embodiments according to the present disclosure. Referring to FIG. 13B, a total number of the one or more second emissive material sub-layers of the third color EM3-2 in the stacked structure of the second emissive material layer ELS2 is two, and a total number of the at least one emissive material sub-layer of the second color EM2 in the stacked structure of the second emissive material layer ELS2 is two.

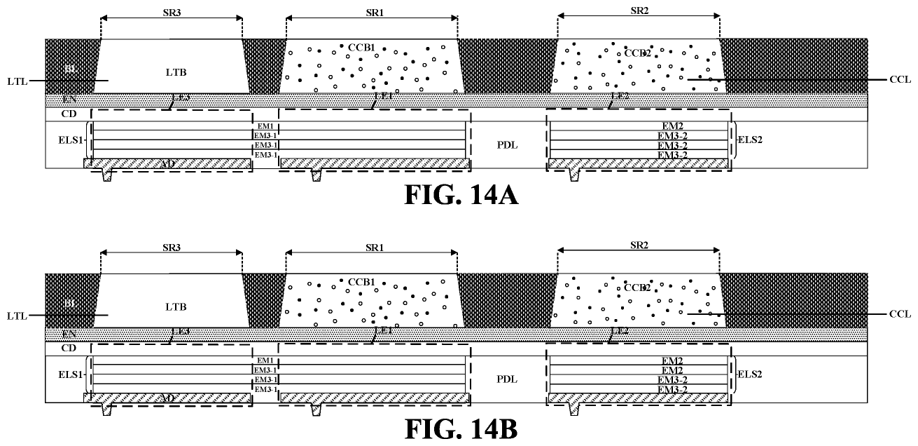

FIG. 14A is a schematic diagram illustrating a first emissive material layer and a second emissive material layer in a display panel in some embodiments according to the present disclosure. Referring to FIG. 14A, the first emissive material layer ELS1 in some embodiments includes a stacked structure comprising one or more first emissive material sub-layers of a third color EM3-1. A total number of the one or more first emissive material sub-layers of the third color EM3-1 in the stacked structure is equal to or greater than two, e.g., 2, 3, 4, or 5. In one example depicted in FIG. 17, a total number of the one or more first emissive material sub-layers of the third color EM3-1 in the stacked structure is four.

In some embodiments, the second emissive material layer ELS2 include a stacked structure comprising one or more second emissive material sub-layers of a third color EM3-2. A total number of the one or more second emissive material sub-layers of the third color EM3-2 in the stacked structure is equal to or greater than two, e.g., 2, 3, 4, or 5. In one example depicted in FIG. 17, a total number of the one or more second emissive material sub-layers of the third color EM3-2 in the stacked structure is three.

In some embodiments, the one or more first emissive material sub-layers of the third color EM3-1 are configured to emit light of the third color in a first wavelength range, and the second emissive material sub-layers of the third color EM3-2 are configured to emit light of the third color in a second wavelength range.

In some embodiments, the stacked structure of the first emissive material layer ELS1 further include at least one emissive material sub-layer of the first color EM1. Optionally, the at least one emissive material sub-layer of the first color EM1 is on a side of the one or more first emissive material sub-layers of a third color EM3-1 closer to the first individual first color conversion block of the plurality of first color conversion blocks of the first color CCB1 in the first subpixel region SR1 and the individual light transmissive block of the plurality of light transmissive blocks LTB in the third subpixel region SR3. Optionally, the at least one emissive material sub-layer of the first color EM1 is configured to emit light of the first color. Optionally, the at least one emissive material sub-layer of the first color EM1 is configured to emit red light.

In some embodiments, the stacked structure of the second emissive material layer ELS2 further include at least one emissive material sub-layer of the second color EM2. Optionally, the at least one emissive material sub-layer of the second color EM2 is on a side of the one or more second emissive material sub-layers of the third color EM3-2 closer to the individual second color conversion block of the plurality of second color conversion blocks of the second color CCB2 in the second subpixel region SR2. Optionally, the at least one emissive material sub-layer of the second color EM2 is configured to emit light of the second color. Optionally, the at least one emissive material sub-layer of the second color EM2 is configured to emit green light having a peak wavelength in a range of 528 nm to 532 nm. Referring to FIG. 14A, a total number of the one or more second emissive material sub-layers of the third color EM3-2 in the stacked structure of the second emissive material layer ELS2 is three, and a total number of the at least one emissive material sub-layer of the second color EM2 in the stacked structure of the second emissive material layer ELS2 is one.

FIG. 14B is a schematic diagram illustrating a first emissive material layer and a second emissive material layer in a display panel in some embodiments according to the present disclosure. Referring to FIG. 14B, a total number of the one or more second emissive material sub-layers of the third color EM3-2 in the stacked structure of the second emissive material layer ELS2 is two, and a total number of the at least one emissive material sub-layer of the second color EM2 in the stacked structure of the second emissive material layer ELS2 is two.

In another aspect, the present disclosure provides a display apparatus, including the display panel described herein or fabricated by a method described herein, and one or more integrated circuits connected to the display panel. Examples of appropriate display apparatuses include, but are not limited to, an electronic paper, a mobile phone, a tablet computer, a television, a monitor, a notebook computer, a digital album, a GPS, etc.

In another aspect, the present disclosure provides a light emitting substrate. In some embodiments, the light emitting substrate includes a first subpixel region configured to emit light of a first color, a second subpixel region configured to emit light of a second color, and a third subpixel region configured to emit light of a third color. Optionally, the light emitting substrate includes a base substrate; and a first light-emitting diode, a second light emitting diode, and a third light-emitting diode on the base substrate. Optionally, the first light-emitting diode includes a first light emitting layer; the second light emitting diode includes a second light emitting layer; and the third light-emitting diode includes a third light emitting layer. Optionally, the second light emitting layer and the third light emitting layer are spaced apart from each other. Optionally, at least a first portion of the first light emitting layer and the third light emitting layer are parts of a unitary layer continuously extending from the third subpixel region to at least a first portion of the first subpixel region. Optionally, an area of the third subpixel region is smaller than an area of the second subpixel region, and is smaller than an area of the first subpixel region. Optionally, the first color, the second color, and the third color are three different colors.

In some embodiments, at least a second portion of the first light emitting layer and the second light emitting layer are parts of a unitary layer continuously extending from the second subpixel region to at least a second portion of the first subpixel region.

In some embodiments, the light of the third color has a wavelength range smaller than a wavelength range of the light of the first color, and smaller than a wavelength range of the light of the second color.

In some embodiments, the light emitting substrate includes a first emissive material layer. Optionally, the first emissive material layer includes the third light emitting layer and the first portion of the first light emitting layer. Optionally, the third light emitting layer and the first portion of the first light emitting layer have a same composition.

In some embodiments, the first emissive material layer includes a stacked structure including multiple first emissive material sub-layers.

In some embodiments, at least two of the multiple first emissive material sub-layers are emissive material sub-layers of a same color.

In some embodiments, all of the multiple first emissive material sub-layers are emissive material sub-layers of a same color.

In some embodiments, at least two of the multiple first emissive material sub-layers are emissive material sub-layers of different colors.

In some embodiments, the light emitting substrate includes a second emissive material layer. Optionally, the second emissive material layer includes the second light emitting layer and the second portion of the first light emitting layer. Optionally, the second light emitting layer and the second portion of the first light emitting layer have a same composition.

In some embodiments, the second emissive material layer includes a stacked structure including multiple second emissive material sub-layers.

In some embodiments, at least two of the multiple second emissive material sub-layers are emissive material sub-layers of different colors.

In some embodiments, the light emitting substrate further includes a second emissive material layer. Optionally, the first emissive material layer includes a stacked structure including one or more first emissive material sub-layers of a third color, the one or more first emissive material sub-layers being configured to emit light of the third color with a first peak wavelength. Optionally, the second emissive material layer includes a stacked structure including one or more second emissive material sub-layers of the third color, the one or more second emissive material sub-layers being configured to emit light of the third color with a second peak wavelength. Optionally, the first peak wavelength and the second peak wavelength are in a wavelength range of blue light. Optionally, the first peak wavelength is different from the second peak wavelength.

In some embodiments, the first peak wavelength is in a range of 460 nm to 463 nm, and the second peak wavelength is in a range of 450 nm to 454 nm.

In some embodiments, the first emissive material layer includes a stacked structure including one or more first emissive material sub-layers configured to emit light of the third color, and at least one emissive material sub-layer configured to emit light of the first color, the at least one emissive material sub-layer being on a side of the one or more first emissive material sub-layers away from the base substrate.

In some embodiments, the second emissive material layer includes a stacked structure including one or more second emissive material sub-layers configured to emit light of the third color, and at least one emissive material sub-layer configured to emit light of the second color, the at least one emissive material sub-layer being on a side of the one or more second emissive material sub-layers away from the base substrate.

In another aspect, the present disclosure provides a method of fabricating a display panel. In some embodiments, the method includes forming a first subpixel region configured to emit light of a first color, forming a second subpixel region configured to emit light of a second color, and forming a third subpixel region configured to emit light of a third color. Optionally, the method includes forming a first light-emitting diode, forming a second light emitting diode, and forming a third light-emitting diode on a base substrate. Optionally, forming the first light-emitting diode includes forming a first light emitting layer; forming the second light emitting diode includes forming a second light emitting layer; and forming the third light-emitting diode includes forming a third light emitting layer. Optionally, the second light emitting layer and the third light emitting layer are spaced apart from each other. Optionally, at least a first portion of the first light emitting layer and the third light emitting layer are formed as parts of a unitary layer continuously extending from the third subpixel region to at least a first portion of the first subpixel region. Optionally, an area of the third subpixel region is smaller than an area of the second subpixel region, and is smaller than an area of the first subpixel region. Optionally, the first color, the second color, and the third color are three different colors.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display panel, comprising a first subpixel region configured to emit light of a first color, a second subpixel region configured to emit light of a second color, and a third subpixel region configured to emit light of a third color;
wherein the display panel comprises:
a base substrate; and
a first light-emitting diode, a second light emitting diode, and a third light-emitting diode on the base substrate;
wherein the first light-emitting diode comprises a first light emitting layer;
the second light emitting diode comprises a second light emitting layer;
the third light-emitting diode comprises a third light emitting layer;
the second light emitting layer and the third light emitting layer are spaced apart from each other;
at least a first portion of the first light emitting layer and the third light emitting layer are parts of a unitary layer continuously extending from the third subpixel region to at least a first portion of the first subpixel region;
an area of the third subpixel region is smaller than an area of the second subpixel region, and is smaller than an area of the first subpixel region; and
the first color, the second color, and the third color are three different colors.

2. The display panel of claim 1, wherein at least a second portion of the first light emitting layer and the second light emitting layer are parts of a unitary layer continuously extending from the second subpixel region to at least a second portion of the first subpixel region.

3. The display panel of claim 1, wherein the light of the third color has a wavelength range smaller than a wavelength range of the light of the first color, and smaller than a wavelength range of the light of the second color.

4. The display panel of claim 1, further comprising a first emissive material layer;
wherein the first emissive material layer comprises the third light emitting layer and the first portion of the first light emitting layer; and
the third light emitting layer and the first portion of the first light emitting layer have a same composition.

5. The display panel of claim 4, wherein the first emissive material layer comprises a stacked structure comprising multiple first emissive material sub-layers.

6. The display panel of claim 5, wherein at least two of the multiple first emissive material sub-layers are emissive material sub-layers of a same color.

7. The display panel of claim 5, wherein all of the multiple first emissive material sub-layers are emissive material sub-layers of a same color.

8. The display panel of claim 5, wherein at least two of the multiple first emissive material sub-layers are emissive material sub-layers of different colors.

9. The display panel of claim 5, wherein the multiple first emissive material sub-layers comprise an emissive material sub-layer of the first color and an emissive material sub-layer of the third color.

10. The display panel of claim 1, comprising a second emissive material layer;
wherein the second emissive material layer comprises the second light emitting layer and the second portion of the first light emitting layer; and
the second light emitting layer and the second portion of the first light emitting layer have a same composition.

11. The display panel of claim 10, wherein the second emissive material layer comprising a stacked structure comprising multiple second emissive material sub-layers; and
at least two of the multiple second emissive material sub-layers are emissive material sub-layers of different colors.

12. (canceled)

13. The display panel of claim 4, further comprising a second emissive material layer;
wherein the first emissive material layer comprises a stacked structure comprising one or more first emissive material sub-layers of a third color, the one or more first emissive material sub-layers being configured to emit light of the third color with a first peak wavelength;
the second emissive material layer comprises a stacked structure comprising one or more second emissive material sub-layers of the third color, the one or more second emissive material sub-layers being configured to emit light of the third color with a second peak wavelength;
the first peak wavelength and the second peak wavelength are in a wavelength range of blue light; and
the first peak wavelength is different from the second peak wavelength.

14. The display panel of claim 13, wherein the first peak wavelength is in a range of 460 nm to 463 nm, and the second peak wavelength is in a range of 450 nm to 454 nm.

15. The display panel of claim 4, wherein the first emissive material layer comprises a stacked structure comprising one or more first emissive material sub-layers configured to emit light of the third color, and at least one emissive material sub-layer configured to emit light of the first color, the at least one emissive material sub-layer being on a side of the one or more first emissive material sub-layers away from the base substrate.

16. The display panel of claim 10, wherein the second emissive material layer comprises a stacked structure comprising one or more second emissive material sub-layers configured to emit light of the third color, and at least one emissive material sub-layer configured to emit light of the second color, the at least one emissive material sub-layer being on a side of the one or more second emissive material sub-layers away from the base substrate.

17. The display panel of claim 1, further comprising a color conversion layer and a light transmissive layer;
wherein the color conversion layer comprises a plurality of first color conversion blocks of a first color;
the light transmissive layer comprises a plurality of light transmissive blocks configured to allow light to transmit through;
an individual light transmissive block of the plurality of light transmissive blocks is at least partially in the third subpixel region;
a first individual first color conversion block of the plurality of first color conversion blocks of the first color is at least partially in the first subpixel region; and
light provided to at least a portion of the first subpixel region and to the third subpixel region are of a same color.

18. The display panel of claim 17, comprising a first emissive material layer;
wherein the first emissive material layer comprises the third light emitting layer and the first portion of the first light emitting layer; and
the third light emitting layer and the first portion of the first light emitting layer have a same composition;
wherein an orthographic projection of the first emissive material layer on the base substrate at least partially overlaps with an orthographic projection of the individual light transmissive block in the third subpixel region on the base substrate, and at least partially overlaps with an orthographic projection of the first individual first color conversion block in at least the portion of the first subpixel region on the base substrate;
wherein the display panel further comprises a bank layer defining a plurality of apertures for receiving a plurality of color conversion blocks and the plurality of light transmissive blocks; and
the orthographic projection of the first emissive material layer on the base substrate at least partially overlaps with an orthographic projection of a portion of the bank layer spacing apart the individual light transmissive block and the first individual first color conversion block on the base substrate.

19. (canceled)

20. The display panel of claim 17, wherein the first subpixel region comprises a first subpixel second region;
wherein the color conversion layer further comprises a plurality of second color conversion blocks of a second color;
an individual second color conversion block of the plurality of second color conversion blocks of the second color is at least partially in the second subpixel region;
a second individual first color conversion block of the plurality of first color conversion blocks of a first color is at least partially in the first subpixel second region; and
light provided to the second subpixel region and the first subpixel second region are of a same color.

21. The display panel of claim 17, comprising a second emissive material layer;
wherein the second emissive material layer comprises the second light emitting layer and a second portion of the first light emitting layer; and
the second light emitting layer and the second portion of the first light emitting layer have a same composition;
wherein an orthographic projection of the second emissive material layer on the base substrate at least partially overlaps with an orthographic projection of the individual second color conversion block in the second subpixel region on the base substrate, and at least partially overlaps with an orthographic projection of the second individual first color conversion block in the first subpixel second region on the base substrate;
wherein the display panel further comprises a bank layer defining a plurality of apertures for receiving a plurality of color conversion blocks and the plurality of light transmissive blocks; and
the orthographic projection of the second emissive material layer on the base substrate at least partially overlaps with an orthographic projection of a portion of the bank layer spacing apart the individual second color conversion block and the second individual first color conversion block on the base substrate.

22. (canceled)

23. A display apparatus, comprising the display panel of claim 1, and one or more integrated circuits connected to the display panel.

24-38. (canceled)
